(19) United States
(12) Patent Application Publication
(10) Pub. No.: US 2026/0090304 A1
(43) Pub. Date: Mar. 26, 2026

(54) SUBSTRATE PROCESSING METHOD AND SUBSTRATE PROCESSING APPARATUS

(71) Applicant: SCREEN Holdings Co., Ltd., Kyoto (JP)

(72) Inventors: Yusuke MAKI, Kyoto (JP); Yusuke TAKEMATSU, Kyoto (JP); Akiyoshi NAKANO, Kyoto (JP); Daijo MIZUKAMI, Kyoto (JP); Mingjhe LI, Kyoto (JP)

(21) Appl. No.: 19/325,434

(22) Filed: Sep. 10, 2025

(30) Foreign Application Priority Data
Sep. 20, 2024 (JP) 2024-164017

(51) Int. Cl. H01L 21/306; H01L 21/02; H01L 21/67

(52) U.S. Cl. CPC H10P 50/642; H10P 70/20; H10P 72/0424

(57) ABSTRACT

A substrate processing method includes preparing a substrate including a silicon layer, which is an example of an etching target that is at least one of silicon and polysilicon; and etching the etching target by supplying the substrate with hot AOM, which is an example of high-temperature ammonia water having a temperature higher than room temperature and an increased dissolved oxygen concentration.

### CROSS REFERENCE TO RELATED APPLICATIONS

This application claims the benefit of priority to Japanese Patent Application No. 2024-164017 filed on Sep. 20, 2024. The entire contents of this application are hereby incorporated herein by reference.

### BACKGROUND OF THE INVENTION

### 1. Field of the Invention

The present invention relates to a substrate processing method and a substrate processing apparatus that process substrates. The substrate includes a semiconductor wafer, a substrate for a FPD (flat panel display) such as a liquid crystal display and an organic EL (electroluminescence) display, a substrate for an optical disc, a substrate for a magnetic disk, a substrate for a magneto-optical disc, a substrate for a photomask, a ceramic substrate, a substrate for a solar cell, and the like.

### 2. Description of Related Art

JP H10112454 A discloses a cleaning method for cleaning a front surface of a semiconductor substrate. In this cleaning method, ozone water is supplied to a cleaning bath in which the semiconductor substrate is accommodated to oxidize the front surface, and then a cleaning liquid in which an ammonia liquid is mixed with the ozone water is generated, and the cleaning liquid is supplied so that the cleaning liquid can be applied to the front surface of the semiconductor substrate.

However, JP H10112454 A does not disclose a temperature of a cleaning liquid in which an ammonia liquid is mixed with ozone water.

At least one embodiment of the present preferred invention provides a substrate processing method and a substrate processing apparatus capable of increasing an etching rate (etching amount per unit time) of an etching target which is at least one of silicon and polysilicon while improving uniformity of etching of the etching target.

### SUMMARY OF THE INVENTION

A preferred embodiment of the present invention provides a substrate processing method including preparing a substrate including an etching target that is at least one of silicon and polysilicon, and etching the etching target by supplying the substrate with high-temperature ammonia water having a temperature higher than room temperature and an increased dissolved oxygen concentration.

In the preferred embodiment, at least one of the following features may be added to the substrate processing method.

The substrate processing method further includes generating the high-temperature ammonia water by mixing ammonia water, ozone water, and hot water having a temperature higher than room temperature.

Etching the etching target includes discharging the high-temperature ammonia water from an etching liquid nozzle, and generating the high-temperature ammonia water includes mixing the ammonia water, the ozone water, and the hot water in a path to the etching liquid nozzle excluding a tank to store the ammonia water.

Etching the etching target includes exposing an etching stop layer covered with the etching target, by etching the etching target, and the high-temperature ammonia water is a liquid that etches the etching stop layer at an etching rate lower than an etching rate of the etching target.

A thickness of the etching stop layer is smaller than a thickness by which the high-temperature ammonia water etches the etching target.

The substrate includes a plate-shaped base material made of a silicon single crystal having a front surface and a rear surface, and a thin film that is in contact with the front surface of the base material. Etching the etching target includes removing the entire base material by etching the base material corresponding to the etching target from the rear surface side of the base material.

The substrate processing method further includes removing a natural oxide film of the etching target by supplying a natural oxide film removing liquid to the substrate before supplying the high-temperature ammonia water to the substrate.

Etching the etching target includes supplying the high-temperature ammonia water to an upper surface of the substrate. The substrate processing method further includes supplying a heating liquid having a temperature higher than room temperature to a lower surface of the substrate in a state where the high-temperature ammonia water is in contact with the upper surface of the substrate.

Etching the etching target includes etching the etching target in a thickness direction of the substrate in an entire region from a center of the substrate to an outer periphery of the substrate to thin an entirety of the substrate by supplying the high-temperature ammonia water to the substrate.

Another preferred embodiment of the present invention provides a substrate processing apparatus including a substrate holder configured to hold a substrate including an etching target that is at least one of silicon and polysilicon, and an etching liquid nozzle configured to etch the etching target by supplying the substrate held by the substrate holder with high-temperature ammonia water having a temperature higher than room temperature and an increased dissolved oxygen concentration. The at least one of the features related to the substrate processing method described above may be added to the substrate processing apparatus.

### BRIEF DESCRIPTION OF THE DRAWINGS

FIGS. 1A, 1B, 1C, and 1D are schematic views illustrating an example of a manufacturing process of a semiconductor device to which a substrate processing method according to a preferred embodiment is applied.

FIG. 2 is a schematic view of an interior of a processing unit provided in the substrate processing apparatus according to the preferred embodiment when viewed horizontally.

FIG. 3 is a schematic view illustrating an AOM supply system provided in the substrate processing apparatus.

FIG. 4 is a process diagram for describing an example of substrate processing performed by the substrate processing apparatus.

FIGS. 5A, 5B, 5C, and 5D are schematic views for describing an example of the processing shown in FIG. 4 and a phenomenon assumed to occur in the substrate when the processing shown in FIG. 4 is performed.

### DETAILED DESCRIPTION OF PREFERRED EMBODIMENTS

Preferred Embodiments of the Present Invention will be explained in detail with reference to the accompanying drawings.

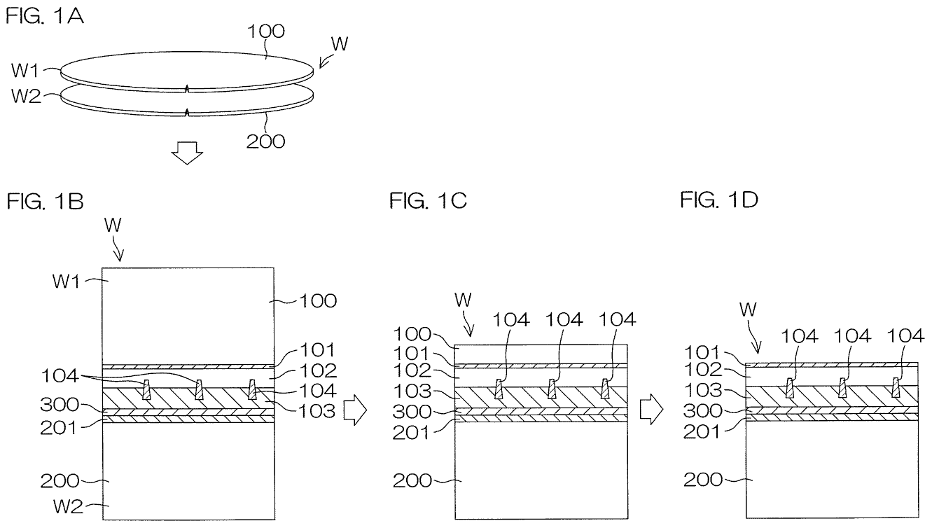

FIGS. 1A, 1B, 1C, and 1D are schematic views illustrating an example of a manufacturing process of a semiconductor device to which a substrate processing method according to a preferred embodiment is applied. FIG. 1A is a perspective view of a first silicon wafer W1 and a second silicon wafer W2 before being bonded. FIGS. 1B, 1C, and 1D are cross-sectional views of the first silicon wafer W1 and the second silicon wafer W2 bonded together.

The bonded substrate W includes a disc-shaped first silicon wafer W1 and a disc-shaped second silicon wafer W2 having equal or substantially equal diameters. The first silicon wafer W1 and the second silicon wafer W2 are bonded such that a front surface of the first silicon wafer W1 and a front surface of the second silicon wafer W2 face each other. FIGS. 1A to 1D illustrate a state where the front surface of the first silicon wafer W1 is directed downward and the front surface of the second silicon wafer W2 is directed upward.

As shown in FIG. 1B, the first silicon wafer W1 includes a silicon layer 100, an etching stop layer 101, and a silicon active layer 102. The silicon layer 100 is an example of a plate-shaped base material made of a silicon single crystal having a front surface and a rear surface. The silicon layer 100 is also an example of an etching target. The etching stop layer 101 is an example of a thin film that is in contact with the front surface of the base material.

The etching stop layer 101 is formed on a front surface of the silicon layer 100. The etching stop layer 101 is, for example, a silicon germanium (SiGe) layer. The etching stop layer 101 may be a thin film of a material other than silicon germanium such as silicon dioxide (SiO₂). The silicon active layer 102 is formed on a front surface of the etching stop layer 101. The silicon active layer 102 is, for example, a silicon epitaxial growth layer epitaxially grown from the etching stop layer 101. In the silicon active layer 102, a semiconductor device (not illustrated) such as a transistor is formed.

A multilayer wiring layer 103 is formed on the silicon active layer 102. The multilayer wiring layer 103 is configured by laminating a wiring layer and an interlayer insulating layer (both layers are not illustrated). A buried power rail 104 (BPR) is disposed across the silicon active layer 102 and the multilayer wiring layer 103. A front surface (lower surface in FIG. 1B) of the multilayer wiring layer 103 corresponds to the front surface of the first silicon wafer W1.

The front surface (lower surface of the multilayer wiring layer 103 in FIG. 1B) of the first silicon wafer W1 is bonded to the front surface (upper surface in FIG. 1B) of the second silicon wafer W2 through an adhesive layer 300. Thereby, the bonded substrate W is prepared. The adhesive layer 300 may include, for example, an SiCN layer. In the example shown in FIGS. 1B to 1D, the second silicon wafer W2 includes a silicon substrate 200 and an insulating layer 201 formed on a front surface of the silicon substrate 200. In this example, a front surface of the insulating layer 201 adheres to the front surface of the multilayer wiring layer 103 of the first silicon wafer W1 through the adhesive layer 300. Therefore, the front surface of the insulating layer 201 and the front surface of the multilayer wiring layer 103 correspond to two bonding surfaces.

The first silicon wafer W1 and the second silicon wafer W2 may be directly bonded without the adhesive layer 300 interposed therebetween (so-called direct bonding). The second silicon wafer W2 may be a wafer on which no semiconductor device is formed (so-called carrier wafer) or a wafer on which a semiconductor device is formed. In the latter case, the semiconductor device formed on the first silicon wafer W1 may be a logic semiconductor device, and the semiconductor device formed on the second silicon wafer W2 may be a memory semiconductor device.

Hereinafter, the bonded substrate W, that is, the first silicon wafer W1 and the second silicon wafer W2 bonded together, is also simply referred to as a substrate W. A rear surface (upper surface in FIGS. 1A to 1D) of the substrate W is a processed surface on which a thinning step to thin the substrate W is performed. The thinning step is a step of removing the silicon layer 100 of the first silicon wafer W1 to expose the etching stop layer 101. That is, the target of the thinning step is the silicon layer 100. After removal of the silicon layer 100, a backside power delivery network (BSPDN) is built that supplies power to the semiconductor devices in the silicon active layer 102 through the power rail 104.

The thinning step includes a grinding step of grinding the silicon layer 100 by friction between abrasive grains and the silicon layer 100, and a wet processing step of supplying a processing liquid such as an etching liquid to a rear surface (upper surface in FIGS. 1B to 1C) of the silicon layer 100 after performing the grinding step. FIG. 1B illustrates a cross section of the substrate W before the grinding step is performed. FIG. 1C illustrates a cross section of the substrate W after the grinding step is performed and before the wet processing step is performed. FIG. 1D illustrates a cross section of the substrate W after the wet processing step is performed. The thickness of the etching stop layer 101 may be equal to the thickness of the silicon layer 100 immediately before the etching liquid is supplied to the silicon layer 100, or may be larger or smaller than the same thickness.

The thinning step may include at least one of a polishing step and a dry etching step in addition to the grinding step and the wet processing step. The polishing step is a step of scraping the silicon layer 100 and smoothing the rear surface of the silicon layer 100 by friction between abrasive grains and the silicon layer 100 after performing the grinding step and before performing the wet processing step. The dry etching step is a step of etching the silicon layer 100 while maintaining a dry state of the substrate W by bringing an etching gas (including at least one of ions and radicals generated from the etching gas) into contact with the rear surface of the silicon layer 100 after performing the grinding step or the polishing step and before performing the wet processing step. The polishing step may be chemical mechanical polishing (CMP).

The wet processing step includes an ammonia-ozone mixture (AOM; a mixed liquid of ammonia water and ozone water) supply step of supplying AOM to the rear surface of the silicon layer 100. As will be described below, in the AOM supply step, a hot AOM having a temperature higher than room temperature (for example, 20 to 30° C.) is supplied. The AOM supply step is a step of removing the silicon layer 100 to expose the etching stop layer 101. After performing the AOM supply step, that is, after removing the AOM from the substrate W, the etching stop layer 101 remains on the substrate W.

The wet processing step may include a plurality of etching liquid supply steps of individually supplying a plurality of types of etching liquid to the rear surface of the silicon layer 100, and at least one rinse liquid supply step of supplying a rinse liquid to the rear surface of the silicon layer 100 before changing the type of etching liquid. The AOM supply step is one of a plurality of etching liquid supply steps.

The plurality of etching liquid supply steps may include at least one of a hydrofluoric nitric acid supply step of supplying hydrofluoric nitric acid which is a mixed liquid of hydrofluoric acid and nitric acid, to the rear surface of the silicon layer 100 before supplying the hot AOM, and a tetramethylammonium hydroxide (TMAH) supply step of supplying TMAH to the rear surface of the silicon layer 100 before supplying the hot AOM. When the plurality of etching liquid supply steps include the AOM supply step, the hydrofluoric nitric acid supply step, and the TMAH supply step, hydrofluoric nitric acid, TMAH, and hot AOM may be supplied to the rear surface of the silicon layer 100 in this order. Hydrofluoric nitric acid, TMAH, and hot AOM are all examples of the etching liquid.

The rate at which the thickness of the substrate W decreases during the wet processing step is lower than the rate at which the thickness of the substrate W decreases during the grinding step. Therefore, the rate at which the thickness of the substrate W decreases when any of hydrofluoric nitric acid, TMAH, and hot AOM is supplied is lower than the rate at which the thickness of the substrate W decreases during the grinding step. The rate at which the hot AOM etches the silicon layer 100 (the amount of etching per unit time) is lower than the rate at which the hydrofluoric nitric acid etches the silicon layer 100 and lower than the rate at which the TMAH etches the silicon layer 100.

When the hot AOM etches the silicon layer 100, the etching stop layer 101 is exposed from the silicon layer 100 and the hot AOM contacts the etching stop layer 101. The hot AOM is a liquid that selectively etches the silicon layer 100 without or with little etching of the etching stop layer 101. The rate at which the hot AOM etches the silicon layer 100 is greater than the rate at which the hot AOM etches the etching stop layer 101. A ratio of the rate at which the silicon layer 100 is etched to the rate at which the etching stop layer 101 is etched is defined as a selection ratio. The selection ratio at the time of supplying the hot AOM is larger than the selection ratio at the time of supplying the hydrofluoric nitric acid and is larger than the selection ratio at the time of supplying the TMAH.

Next, a substrate processing apparatus 1 that performs the above-described wet processing step will be described.

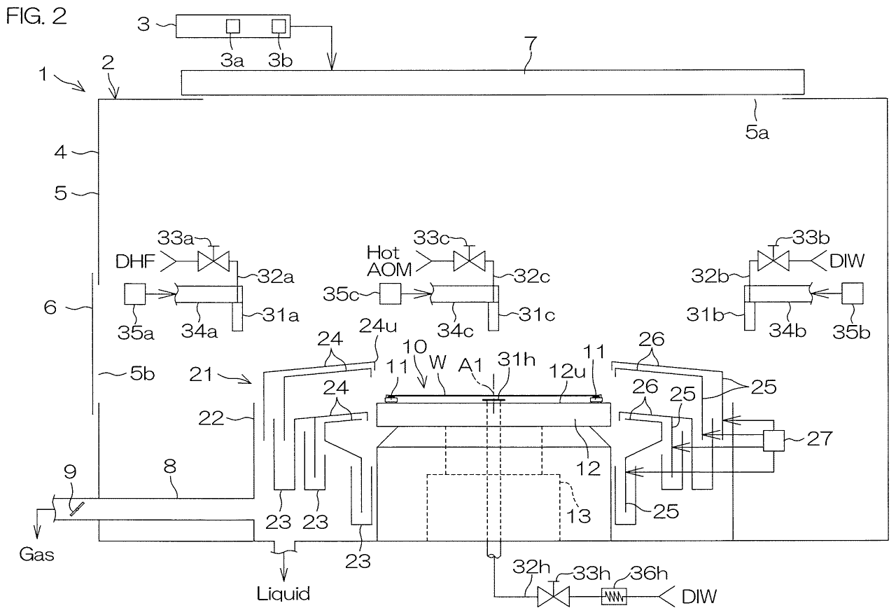

FIG. 2 is a schematic view of an interior of a processing unit 2 provided in the substrate processing apparatus 1 according to the preferred embodiment when viewed horizontally. The substrate processing apparatus 1 is a single substrate processing type apparatus that processes disc-shaped substrates W one by one. The substrate processing apparatus 1 includes a load port that holds a carrier housing a plurality of substrates W such as a FOUP (Front-Opening Unified Pod), a plurality of processing units 2 that process the substrates W transferred from the carrier on the load port with a processing fluid such as a processing liquid or processing gas, a transfer system that transfers the substrate W between the carrier on the load port and the plurality of processing units 2, and a controller 3 that controls the substrate processing apparatus 1.

The controller 3 controls electrical devices and electronic devices provided in the substrate processing apparatus 1. The controller 3 includes at least one computer that can communicate with each other. The computer includes a memory 3b that stores information such as a program, and a CPU 3a (central processing unit) that controls the substrate processing apparatus 1 according to the program stored in the memory 3b. The controller 3 performs processing of the substrate W described below and the like by controlling the substrate processing apparatus 1. In other words, the controller 3 is programmed to perform processing of the substrate W described below and the like.

FIG. 2 shows one of the plurality of processing units 2. Each processing unit 2 is a wet processing unit that performs at least the above-described wet processing step. The processing unit 2 includes a chamber 4 that accommodates the substrate W, and a spin chuck 10 that rotates one substrate W around a vertical rotational axis A1 passing through a central portion of the substrate W while horizontally holding the substrate W in the chamber 4.

The chamber 4 includes a box-shaped partition 5 provided with a passing opening 5b through which the substrate W passes, and a door 6 that opens and closes the passing opening 5b. An FFU 7 (fan filter unit 7) is disposed on an air outlet 5a provided in the upper portion of the partition 5. The FFU 7 constantly supplies clean air (air that has been filtered by a filter) into the chamber 4 from the air outlet 5a. The gas in the chamber 4 is discharged from the chamber 4 through a discharged gas duct 8 connected to the bottom portion of a processing cup 21 described below. Thereby, a downflow of clean air is constantly formed inside the chamber 4. The flow rate of discharged gas to be discharged into the discharged gas duct 8 is changed according to the opening degree of an discharged gas valve 9 disposed in the discharged gas duct 8.

The spin chuck 10 includes a disc-shaped spin base 12 horizontally held, a plurality of chuck pins 11 that hold the substrate W horizontally above the spin base 12, and a spin motor 13 that rotates the spin base 12 and the plurality of chuck pins 11 around the rotational axis A1. The spin chuck 10 is not limited to a mechanical chuck that brings the plurality of chuck pins 11 into contact with the end surface of the substrate W, and may be a vacuum chuck that holds the substrate W horizontally by adsorbing the lower surface of the substrate W onto the upper surface 12u of the spin base 12. When the spin chuck 10 is the mechanical chuck, the plurality of chuck pins 11 correspond to a substrate holder. When the spin chuck 10 is the vacuum chuck, the spin base 12 corresponds to the substrate holder.

The processing unit 2 includes the tubular processing cup 21 that receives processing liquid scattered from the substrate W. The processing cup 21 includes a plurality of guards 24 that receive processing liquid discharged outward from the substrate W held by the spin chuck 10, a plurality of cups 23 that receive the processing liquid guided downward by the plurality of guards 24, and a tubular outer wall 22 surrounding the plurality of guards 24 and the plurality of cups 23. FIG. 2 shows an example where four guards 24 and three cups 23 are provided and the outermost cup 23 is integral with the 3rd guard 24 from the top.

The guard 24 includes a cylindrical portion 25 surrounding the spin chuck 10, and a toric ceiling portion 26 extending upward obliquely from the upper end portion of the cylindrical portion 25 toward the rotational axis A1. The plurality of ceiling portions 26 overlap in the vertical direction, and the plurality of cylindrical portions 25 are disposed in a concentric manner. The toric upper end of the ceiling portion 26 corresponds to the upper end 24u of the guard 24 surrounding the substrate W and the spin base 12 in a plan view. The plurality of cups 23 are disposed under the plurality of cylindrical portions 25, respectively. The cup 23 forms an annular groove that receives processing liquid guided downward by the guard 24.

The processing unit 2 includes a raising/lowering actuator 27 that individually raises and lowers the plurality of guards 24. The raising/lowering actuator 27 keeps the guard 24 stationary at an arbitrary position within a range from an upper position to a lower position. FIG. 2 shows a state where two guards 24 are disposed at the upper positions and the remaining two guards 24 are disposed at the lower positions. The upper position is a position where the upper end 24u of the guard 24 is disposed above a holding position where the substrate W held by the spin chuck 10 is positioned. The lower position is a position where the upper end 24u of the guard 24 is disposed below the holding position.

The actuator is a device that converts driving energy, which represents electrical, fluid, magnetic, thermal or chemical energy, to mechanical work, that is, motion of a tangible object. The actuator includes an electric motor (rotary motor), linear motor, air cylinder and other devices. If the motion of the actuator is different from the motion of the object, a motion converter may be provided to convert the motion of the actuator into linear motion or rotation. For example, if the actuator is an electric motor and the object is to be moved in a linear motion, a motion converter, such as a ball screw and ball nut, may convert the rotation of the electric motor into linear motion.

The processing unit 2 includes a plurality of nozzles that discharge processing fluid such as processing liquid or processing gas toward the substrate W held by the spin chuck 10. The plurality of nozzles include a chemical nozzle 31a, a rinse nozzle 31b, an etching nozzle 31c and the like.

The chemical nozzle 31a is a nozzle to discharge chemical liquid toward the upper surface of the substrate W. The rinse nozzle 31b is a nozzle to discharge rinse liquid toward the upper surface of the substrate W. The etching nozzle 31c is a nozzle to discharge etching liquid toward the upper surface of the substrate W. FIG. 2 shows an example where the chemical liquid is DHF (Dilute Hydrogen Fluoride), the rinse liquid is DIW (pure water) and the etching liquid is Hot AOM (mixed liquid of ammonia water, ozone water and hot water).

The chemical nozzle 31a may be a scan nozzle that moves a collision position of the chemical liquid with respect to the substrate W within the upper surface of the substrate W or may be a fixed nozzle that cannot move the collision position of the chemical liquid with respect to the substrate W. The same applies to other nozzles. FIG. 2 shows an example where the chemical nozzle 31a, the rinse nozzle 31b, and the etching nozzle 31c are scan nozzles.

The chemical nozzle 31a is connected to a first nozzle actuator 35a that moves the chemical liquid nozzle 31a in at least one of the vertical and horizontal directions. The chemical nozzle 31a extends downward from a first nozzle arm 34a horizontally extending in the chamber 4. The first nozzle actuator 35a moves the chemical nozzle 31a by moving the first nozzle arm 34a.

The rinse nozzle 31b is connected to a second nozzle actuator 35b that moves the chemical liquid nozzle 31a in at least one of the vertical and horizontal directions. The rinse nozzle 31b extends downward from a second nozzle arm 34b horizontally extending in the chamber 4. The second nozzle actuator 35b moves the rinse nozzle 31b by moving the second nozzle arm 34b.

The etching nozzle 31c is connected to a third nozzle actuator 35c that moves the chemical liquid nozzle 31a in at least one of the vertical and horizontal directions. The etching nozzle 31c extends downward from a third nozzle arm 34c horizontally extending in the chamber 4. The third nozzle actuator 35c moves the etching nozzle 31c by moving the third nozzle arm 34c.

The first nozzle actuator 35a moves the chemical liquid nozzle 31a horizontally between a processing position at which the chemical liquid discharged from the chemical liquid nozzle 31a is supplied to the upper surface of the substrate W and a standby position at which the chemical liquid nozzle 31a is positioned around the processing cup 21 in a plan view. The same applies to the second nozzle actuator 35b and the third nozzle actuator 35c. FIG. 2 shows a state where the chemical liquid nozzle 31a and the rinse nozzle 31b are disposed at the standby positions and the etching nozzle 31c is disposed at the processing position.

The chemical liquid nozzle 31a is connected to chemical liquid piping 32a that guides chemical liquid. When a chemical liquid valve 33a attached to the chemical liquid piping 32a is opened, an outlet of the chemical liquid nozzle 31a continuously discharges the chemical liquid downward. The chemical liquid may be a liquid containing at least one of sulfuric acid, nitric acid, hydrochloric acid, hydrofluoric acid, phosphoric acid, acetic acid, ammonia water, hydrogen peroxide water, organic acid (for example, citric acid, oxalic acid, etc.), organic alkali (for example, TMAH: tetramethylammonium hydroxide, etc.), surfactant, and corrosion inhibitor, or may be a liquid other than this.

Although not shown, the chemical liquid valve 33a includes a valve body provided with an annular valve seat through which chemical liquid passes, a valve element that can move with respect to the valve seat, and an actuator that moves the valve element between a closed position where the valve element contacts the valve seat and an open position where the valve element is away from the valve seat. The same applies to other valves. The actuator may be a pneumatic actuator or an electric actuator, or may be an actuator other than these. The controller 3 opens and closes the chemical liquid valve 33a and the like by controlling the actuator.

The rinse liquid nozzle 31b is connected to rinse liquid piping 32b that guides rinse liquid. When a rinse liquid valve 33b attached to the rinse liquid piping 32b is opened, an outlet of the rinse liquid nozzle 31b continuously discharges the rinse liquid downward. The rinse liquid may be any of pure water (DIW (Deionized Water)), carbonated water, electrolyzed ionized water, hydrogen water, ozone water, hydrochloric acid water having a dilution concentration (for example, about 1 to 100 ppm) and ammonia water having a dilution concentration (for example, about 1 to 100 ppm), or may be a liquid other than these.

The etching liquid nozzle 31c is connected to etching liquid piping 32c that guides etching liquid. When an etching liquid valve 33c attached to the etching liquid piping 32c is opened, an outlet of the etching liquid nozzle 31c continuously discharges the etching liquid downward. The etching liquid is hot AOM (mixed liquid of ammonia water, ozone water and hot water) having a temperature higher than room temperature.

The plurality of nozzles include, in addition to the chemical nozzle 31a and the like, a lower surface nozzle 31h to discharge processing liquid toward the central portion of the lower surface of the substrate W. The lower surface nozzle 31h includes a disc portion disposed between the upper surface 12u of the spin base 12 and the lower surface of the substrate W, and a cylindrical portion extending downward from the disc portion. The outlet of the lower surface nozzle 31h opens at the central portion of the upper surface of the disc portion. When the substrate W is held by the spin chuck 10, the outlet of the lower surface nozzle 31h faces vertically to the central portion of the lower surface of the substrate W.

The lower surface nozzle 31h is connected to rinse liquid piping 32h that guides rinse liquid. FIG. 2 shows an example where the rinse liquid is pure water. When a rinse liquid valve 33h attached to the rinse liquid piping 32 h is opened, the rinse liquid is continuously discharged in the upper direction from the outlet of the lower surface nozzle 31h. FIG. 2 shows an example where a heater 36h is provided to heat the pure water to be supplied to the lower surface nozzle 31h from the rinse liquid piping 32h. In this example, hot water (pure water having a temperature higher than room temperature), which is an example of a heating liquid, is supplied to the substrate W from the lower surface nozzle 31h.

Next, an AOM supply system that supplies the hot AOM to the substrate W will be described.

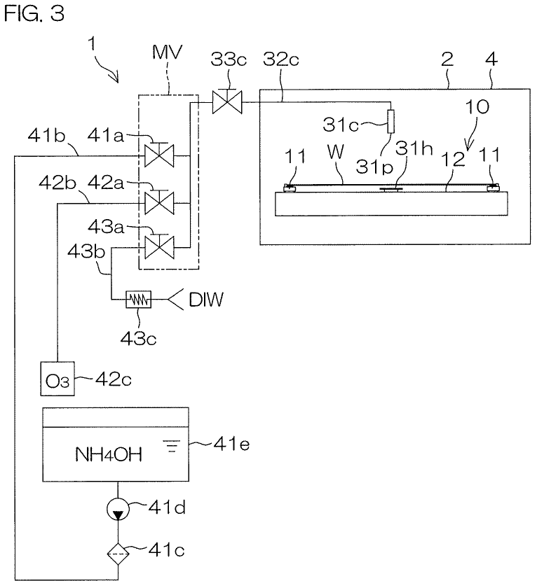

FIG. 3 is a schematic view illustrating the AOM supply system provided in the substrate processing apparatus 1. The substrate processing apparatus 1 includes the AOM supply system that supplies hot AOM to the substrate W. The AOM supply system includes an etching liquid nozzle 31c, an etching liquid piping 32c, and an etching liquid valve 33c. The AOM supply system further includes a tank 41e that stores ammonia water, an ozone water generator 42c that generates ozone water by dissolving ozone gas in pure water, and a hot water heater 43c that generates hot water by heating pure water. The tank 41e, the ozone water generator 42c, and the hot water heater 43c are disposed outside the chamber 4.

The etching liquid nozzle 31c includes a discharge port 31p to discharge the hot AOM toward the upper surface of the substrate W. The discharge port 31p is open on an outer surface of the etching liquid nozzle 31c, and vertically faces the upper surface of the substrate W at an interval. FIG. 3 shows an example in which ozone water and hot water are mixed with ammonia water in a path to the discharge port 31p of the etching liquid nozzle 31c excluding the tank 41e. In this example, an ammonia water piping 41b, an ozone water piping 42b, and a hot water piping 43b are connected to the etching liquid piping 32c, and ammonia water, ozone water, and hot water are mixed in the etching liquid piping 32c. The ozone water and the hot water may be mixed with the ammonia water in the tank 41e.

In the example shown in FIG. 3, ammonia water is sent from the tank 41e to the ammonia water piping 41b by a pump 41d. Foreign matters contained in the ammonia water are removed by a filter 41c attached to the ammonia water piping 41b. When an ammonia water valve 41a attached to the ammonia water piping 41b is opened, the ammonia water in the tank 41e is supplied to the etching liquid piping 32c through the ammonia water piping 41b. When an ozone water valve 42a attached to the ozone water piping 42b is opened, ozone water generated by an ozone water generator 42c is supplied to the etching liquid piping 32c through the ozone water piping 42b. When a hot water valve 43a attached to the hot water piping 43b is opened, hot water generated by a hot water heater 43c is supplied to the etching liquid piping 32c through the hot water piping 43b.

FIG. 3 shows an example in which the ammonia water valve 41a, the ozone water valve 42a, and the hot water valve 43a are portion of a mixing valve MV. The ammonia water valve 41a is a valve that serves as both an opening/closing valve that switches between an open state where a liquid such as ammonia water passes and a closed state where the liquid stops and a flow control valve that stabilizes a flow rate of the passing liquid at an arbitrary value within a certain range. The same applies to the ozone water valve 42a and the hot water valve 43a. Instead of the ammonia water valve 41a, an opening/closing valve and a flow control valve may be attached as separate valves to the etching liquid piping 32c. The same applies to other pipings.

When the ammonia water valve 41a, the ozone water valve 42a, and the hot water valve 43a are opened, ammonia water, ozone water, and hot water are mixed in the etching liquid piping 32c at a mixing ratio corresponding to the opening degrees of the ammonia water valve 41a, the ozone water valve 42a, and the hot water valve 43a. As a result, an etching liquid corresponding to a mixed liquid of ammonia water, ozone water, and hot water is supplied from the etching liquid piping 32c to the etching liquid nozzle 31c, and is discharged from the discharge port 31p of the etching liquid nozzle 31c.

Ammonia water is also referred to as ammonium hydroxide (NH₄OH). The mixed liquid of ammonia water, ozone water, and hot water is a liquid obtained by mixing ozone water with diluted ammonia water (dNH₄OH) diluted with hot water. The ammonia-ozone mixture (AOM) is a mixed liquid of ammonia water and ozone water. The mixed liquid of ammonia water, ozone water, and hot water is included in the AOM. The mixed liquid of ammonia water, ozone water, and hot water is a hot AOM having a temperature higher than room temperature.

As long as the temperature of hot AOM is higher than room temperature, ammonia water, ozone water, and hot water may be at any temperature. The temperature of hot water is higher than the temperature of ammonia water. The temperature of hot water is higher than the temperature of ozone water. The temperature of ammonia water may be equal to or different from the temperature of ozone water. The temperature of ammonia water may be room temperature or take a value different from room temperature. The same applies to ozone water.

The concentration of ozone gas in ozone water is higher than the concentration of ozone gas in ammonia water. The concentration of ozone gas in ozone water is higher than the concentration of ozone gas in hot water. A plurality of ozone molecules in ozone water are changed into a plurality of oxygen molecules. This increases the dissolved oxygen concentration of ozone water. The dissolved oxygen concentration of ozone water is higher than the dissolved oxygen concentration of ammonia water. The dissolved oxygen concentration of ozone water is higher than the dissolved oxygen concentration of hot water. The dissolved oxygen concentration of ammonia water may be equal to or different from the dissolved oxygen concentration of hot water. Ammonia water may be a liquid for which the dissolved oxygen concentration is not adjusted, or may be a liquid for which the dissolved oxygen concentration is increased or decreased. The same applies to hot water.

The concentration of ozone gas in hot AOM may be a saturated concentration of ozone gas at the temperature of hot AOM or may be less than the saturated concentration. When conditions such as temperature are the same, the solubility of ozone gas in water is higher than the solubility of oxygen gas in water. Therefore, if ozone water, which is water in which ozone gas is dissolved, is mixed with ammonia water, the dissolved oxygen concentration of hot AOM can be increased to a value larger than that in a case where oxygen water, which is water in which oxygen gas is dissolved, is mixed with ammonia water.

When the diameter of the disc-shaped substrate W is 300 mm, the flow rate of hot AOM supplied to the upper surface of the substrate W may be 2000 ml/min or less. The concentration of ammonia in hot AOM is, for example, 0.5 to 5.0 wt % or volt, and the concentration of ozone water is, for example, 10 to 50 ppm. For example, ozone water at 30 ppm is mixed at 50 ml/min with ammonia water flowing at 2000 ml/min. The temperature of hot AOM may be ranged between room temperature or more and 90° C. or less. The concentration of ammonia in ammonia water may be 0.5 to 5.0 wt % or vol %. The concentration of ozone gas in ozone water may be 5 to 80 ppm. The temperature of the hot water may be 40 to 89.9° C.

Hereinafter, an example in which ammonia water at room temperature having an ammonia concentration of 0.5 to 5.0 wt % or vol %, ozone water at room temperature having an ozone gas concentration of 5 to 80 ppm, and hot water at 40 to 89.9° C. are mixed so that hot AOM is supplied to the substrate W at about 2000 ml/min will be described. In this example, the flow rate of ammonia water is 95 ml/min, the flow rate of ozone water is 33.3 to 400 ml/min, and the flow rate of hot water is 1505 to 1871.7 ml/min.

When hot water as an example of a heating liquid is discharged from a lower surface nozzle 31h toward the lower surface of the substrate W, the temperature of the hot water may be equal to or different from the temperature of hot AOM. In this case, the temperature of hot water discharged from the lower surface nozzle 31h may be equal to or different from the temperature of hot water used to generate hot AOM. The temperature of hot water discharged from the lower surface nozzle 31h may be ranged between room temperature or more and 90° C. or less. The flow rate of hot water discharged from the lower surface nozzle 31h may be a value exceeding 0 and equal to or less than 2000 ml/min. That is, the flow rate of the heating liquid discharged toward the lower surface of the substrate W may be equal to or different from the flow rate of hot AOM discharged toward the upper surface of the substrate W.

Next, an example of processing of the substrates W shall be described.

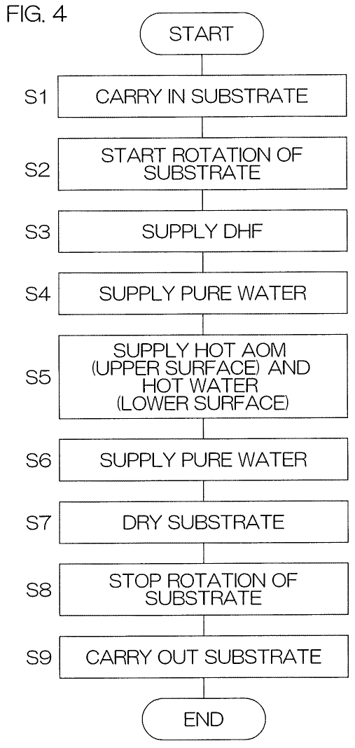

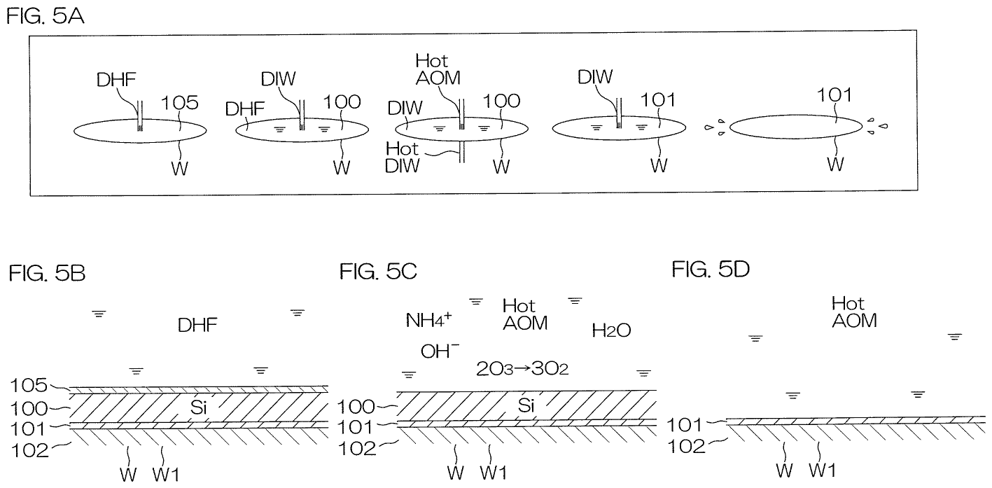

FIG. 4 is a process diagram for describing an example of processing for the substrate W performed by the substrate processing apparatus 1. FIG. 5A is a schematic view for describing the same example. In the following, FIG. 2, FIG. 4, and FIG. 5A shall be referenced. DIW in FIG. 5A represents pure water.

When the substrate W is to be processed by the substrate processing apparatus 1, a carry-in step (step S1 of FIG. 4) of carrying the substrate W into the chamber 4 is performed.

Specifically, with all the guards 24 located at the down position and all the nozzles at the ready position, a transfer system (not shown) places the substrate W on a hand (not shown) over the plurality of chuck pins 11 with the silicon layer 100 (see FIG. 1C) facing up, and then retracts the hand from inside the chamber 4. When the substrate W is placed on the plurality of chuck pins 11, all the chuck pins 11 are pressed against the end surface of the substrate W, and the substrate W is held by the spin chuck 10. Thereafter, the spin motor 13 is driven, and the rotation of the substrate W is started (step S2 in FIG. 4).

Next, a chemical liquid supply step (step S3 in FIG. 4) of supplying DHF, which is an example of a chemical liquid, to the upper surface of the substrate W to form a liquid film of DHF covering the entire upper surface of the substrate W is performed.

Specifically, the first nozzle actuator 35a moves the chemical liquid nozzle 31a from the standby position to the processing position in a state where the at least one guard 24 is located at the upper position. Thereafter, the chemical liquid valve 33a is opened, and the chemical liquid nozzle 31a starts discharging DHF. When a predetermined time elapses after the chemical liquid valve 33a is opened, the chemical liquid valve 33a is closed, and the discharge of DHF is stopped. Thereafter, the first nozzle actuator 35a moves the chemical liquid nozzle 31a to the standby position.

As shown at the left end of FIG. 5A, DHF discharged from the chemical liquid nozzle 31a collides with the upper surface of the substrate W rotating at a chemical liquid supply speed, and then flows outward along the upper surface of the substrate W. Therefore, DHF is supplied to the entire upper surface of the substrate W, and a liquid film of DHF covering the entire upper surface of the substrate W is formed. When the chemical liquid nozzle 31a is discharging DHF, the first nozzle actuator 35a may move the collision position so that the collision position of DHF with respect to the upper surface of the substrate W passes through the central portion and the outer peripheral portion, or may stop the collision position at the central portion. The same applies to the processing liquid supplied to the upper surface of the substrate W after DHF as to whether or not to move the collision position.

Next, a first rinse liquid supply step (step S4 in FIG. 4) of supplying pure water, which is an example of a rinse liquid, to the upper surface of the substrate W and washing away DHF on the substrate W is performed.

Specifically, the second nozzle actuator 35b moves the rinse liquid nozzle 31b from the standby position to the processing position in a state where the at least one guard 24 is located at the upper position. Thereafter, the rinse liquid valve 33b is opened, and the rinse liquid nozzle 31b starts discharging pure water. Before the discharge of the pure water is started, the raising/lowering actuator 27 may vertically move at least one guard 24 in order to switch the guard 24 that receives the liquid discharged from the substrate W. The same applies to a processing liquid that will be supplied to the upper surface of the substrate W after pure water as to whether or not to switch the guard 24 that receives the liquid discharged from the substrate W.

As shown second from the left in FIG. 5A, the pure water discharged from the rinse liquid nozzle 31b collides with the upper surface of the substrate W rotating at a rinse liquid supply speed, and then flows outward along the upper surface of the substrate W. The DHF on the substrate W is replaced with pure water discharged from the rinse liquid nozzle 31b. As a result, a liquid film of pure water covering the entire upper surface of the substrate W is formed. When a predetermined time elapses after the rinse liquid valve 33b is opened, the rinse liquid valve 33b is closed and the discharge of pure water is stopped. Thereafter, the second nozzle actuator 35b moves the rinse liquid nozzle 31b to the standby position.

Next, the AOM supply step (step S5 in FIG. 4) of supplying hot AOM, which is an example of an etching liquid, to the upper surface of the substrate W to form a liquid film of hot AOM covering the entire upper surface of the substrate W is performed.

Specifically, in a state where the at least one guard 24 is located at the upper position, the third nozzle actuator 35c moves the etching liquid nozzle 31c from the standby position to the processing position. Thereafter, the etching liquid valve 33c is opened, and the etching liquid nozzle 31c starts discharging hot AOM.

As shown third from the left in FIG. 5A, hot AOM discharged from the etching liquid nozzle 31c collides with the upper surface of the substrate W rotating at an etching liquid supply speed, and then flows outward along the upper surface of the substrate W. The pure water on the substrate W is replaced with hot AOM discharged from the etching liquid nozzle 31c. As a result, a liquid film of the hot AOM covering the entire upper surface of the substrate W is formed. When a predetermined time elapses after the etching liquid valve 33c is opened, the etching liquid valve 33c is closed, and the discharge of hot AOM is stopped. Thereafter, the third nozzle actuator 35c moves the etching liquid nozzle 31c to the standby position.

When the etching liquid nozzle 31c is discharging hot AOM toward the upper surface of the substrate W, the lower surface nozzle 31h may or may not discharge a heating liquid having a temperature higher than room temperature, such as hot water, toward the lower surface of the substrate W. FIGS. 4 and 5A illustrate an example in which hot water is discharged from the lower surface nozzle 31h while hot AOM is discharged from the etching liquid nozzle 31c. The discharge of hot water from the lower surface nozzle 31h may be started at the same time as the etching liquid nozzle 31c starts discharging hot AOM, or may be started before or after the etching liquid nozzle 31c starts discharging hot AOM. The discharge of hot water from the lower surface nozzle 31h may be stopped at the same time as the etching liquid nozzle 31c starts discharging hot AOM, or may be stopped before or after the etching liquid nozzle 31c starts discharging hot AOM.

Next, a second rinse liquid supply step (step S6 in FIG. 4) of supplying pure water, which is an example of a rinse liquid, to the upper surface of the substrate W and washing away hot AOM on the substrate W is performed.

Specifically, the second nozzle actuator 35b moves the rinse liquid nozzle 31b from the standby position to the processing position in a state where the at least one guard 24 is located at the upper position. Thereafter, the rinse liquid valve 33b is opened, and the rinse liquid nozzle 31b starts discharging pure water. As shown fourth from the left in FIG. 5A, a liquid film of pure water covering the entire upper surface of the substrate W is thereby formed. When a predetermined time elapses after the rinse liquid valve 33b is opened, the rinse liquid valve 33b is closed and the discharge of pure water is stopped. Thereafter, the second nozzle actuator 35b moves the rinse liquid nozzle 31b to the standby position.

Next, a drying step (step S7 in FIG. 4) of drying the substrate W by the rotation of the substrate W is performed.

Specifically, the spin motor 13 accelerates the substrate W in a rotation direction, and rotates the substrate W at the highest drying speed (for example, several thousand rpm) in the example of the processing of the substrate W shown in FIG. 4. As shown at the right end of FIG. 5A, when the spin motor 13 starts high-speed rotation of the substrate W, the liquid scatters outward from the substrate W and is removed from the substrate W. As a result, the substrate W is dried. When a predetermined time elapses from when the high speed rotation of the substrate W was started, the spin motor 13 stops rotating. The rotation of the substrate W is thereby stopped (step S8 of FIG. 4).

Next, a carry-out step (step S9 of FIG. 4) of carrying out the substrate W from the chamber 4 is performed.

Specifically, the raising/lowering actuator 27 lowers all the guards 24 to the lower position. Thereafter, the transfer system (not shown) causes the hand (not shown) to enter the chamber 4. In the transfer system, after the plurality of chuck pins 11 release the gripping of the substrate W, the substrate W on the spin chuck 10 is supported by the hand. Thereafter, the transfer system retracts the hand from the inside of the chamber 4 while supporting the substrate W with the hand. The processed substrate W is thereby carried out from the chamber 4.

Next, a phenomenon assumed to occur in the substrate W when the processing shown in FIG. 4 is performed will be described.

FIGS. 5B, 5C, and 5D are schematic cross-sectional views of the substrate W for describing this phenomenon. When the silicon layer 100 comes into contact with air, the surface layer of the silicon layer 100 changes to a natural oxide film 105 of silicon, that is, a thin film of silicon dioxide. FIG. 5B shows a state where DHF, which is an example of the natural oxide film removing liquid, is in contact with the natural oxide film 105.

As shown in FIGS. 5B and 5C, when DHF is supplied to the substrate W, the natural oxide film 105 is dissolved in DHF and removed from the silicon layer 100. As a result, the single crystal of silicon constituting the rear surface (upper surface in FIGS. 5B and 5C) of the silicon layer 100 is exposed. In a case where the dry etching step is included in the thinning step, particles generated on the rear surface of the silicon layer 100 when the dry etching step is performed are removed from the silicon layer 100 together with the natural oxide film 105.

When hot AOM is supplied to the substrate W after replacing DHF on the substrate W with pure water, hot AOM comes into contact with the rear surface of the silicon layer 100, that is, the single crystal of silicon, as shown in FIG. 5C. Si in FIGS. 5B and 5C represents a single crystal of silicon. The single crystal of silicon dissolves in hot AOM. Therefore, as shown in FIG. 5D, the silicon layer 100 is etched in the thickness direction of the substrate W over the entire region from the center of the substrate W to the outer periphery of the substrate W, and the etching stop layer 101 is exposed over the entire region of the rear surface of the substrate W (see also FIG. 5A).

As shown in FIG. 5C, the plurality of ozone molecules are changed into a plurality of oxygen molecules. Therefore, when ozone water is dissolved in ammonia water, ammonia water is diluted with ozone water, and the dissolved oxygen concentration of ammonia water increases. Oxygen molecules in hot AOM oxidize the rear surface of the silicon layer 100. Ozone molecules in hot AOM also oxidize the rear surface of the silicon layer 100. As a result, it is assumed that excessive etching of the silicon layer 100 by ammonia water is inhibited, and uniformity of etching of the silicon layer 100 is improved.

On the other hand, since ozone water and hot water are mixed with ammonia water, ammonia water is diluted with ozone water and hot water, and ammonia water and ozone water are heated with hot water. As a result, a hot AOM having a temperature higher than room temperature is generated. Therefore, the etching rate (etching amount per unit time) of the silicon layer 100 is increased. Therefore, it is possible to shorten the time required to etch the silicon layer 100 while improving the uniformity of etching of the silicon layer 100.

In general, when the nozzle is scanned while the substrate W is rotated (when the collision position of the processing liquid is moved in the upper surface of the substrate W while the substrate W is rotated), the uniformity of the processing is improved as compared with the case where the collision position of the processing liquid is stopped at the central portion of the upper surface of the substrate W. It has been confirmed that, in a case where hot AOM is supplied to the upper surface of the substrate W while the substrate W is rotated, even if the collision position of hot AOM is stopped at the central portion of the upper surface of the substrate W, uniformity equal to or higher than that in a case where the collision position of hot AOM is moved in the upper surface of the substrate W can be obtained.

Next, the advantages according to the preferred embodiment will be described.

In the present preferred embodiment, hot AOM corresponds to high-temperature ammonia water having a temperature higher than room temperature and an increased dissolved oxygen concentration. Such a hot AOM is supplied to the substrate W. As a result, hot AOM comes into contact with the silicon layer 100, which is an example of the etching target, and etches the silicon layer 100. Since the dissolved oxygen concentration of hot AOM is increased, the uniformity of etching of the silicon layer 100 can be improved. Furthermore, since the temperature of hot AOM is increased, the etching rate of the silicon layer 100 can be increased while improving the uniformity of etching of the silicon layer 100.

In the present preferred embodiment, hot AOM, which is a mixed liquid of ammonia water, ozone water, and hot water, is generated by mixing ammonia water, ozone water, and hot water. Ammonia water and ozone water are heated by hot water. As a result, the temperature of hot AOM can be increased to a value higher than room temperature. The plurality of ozone molecules in hot AOM change into a plurality of oxygen molecules. This increases the dissolved oxygen concentration of hot AOM. Oxygen molecules in hot AOM oxidize the rear surface of the silicon layer 100. Ozone molecules in hot AOM also oxidize the rear surface of the silicon layer 100. As a result, it is assumed that excessive etching of the silicon layer 100 by ammonia water is inhibited, and uniformity of etching of the silicon layer 100 is improved.

When the etching target such as silicon or polysilicon is etched with ammonia water, oxygen in the air is dissolved in ammonia water, and the uniformity of etching of the etching target may be decreased. By dispersing ozone gas, which is an example of an oxidizing agent, in ammonia water, it is possible to reduce or prevent a decrease in uniformity caused by oxygen in the air. Furthermore, it was confirmed that when ozone water was added to ammonia water, the etching rate of the etching target was hardly changed, while the uniformity of etching of the etching target was improved. Therefore, the uniformity of etching of the etching target can be improved with little influence on the etching rate of the etching target.

In the present preferred embodiment, ammonia water, ozone water, and hot water are mixed not in the tank 41e to store ammonia water but in the path to the etching liquid nozzle 31c. Therefore, as compared with the case where ammonia water, ozone water, and hot water are mixed in the tank 41e, it is possible to shorten the time from when they are mixed until they are supplied to the substrate W. The rate at which ozone molecules in the liquid are decomposed increases with an increase in the temperature of the liquid. The rate increases as the pH (hydrogen ion index) of the liquid increases. Hot AOM is a liquid having a temperature higher than room temperature and a pH greater than 7. Therefore, ozone molecules in hot AOM decompose in a short time. By shortening the time from the mixing of ammonia water, ozone water, and hot water to the supply to the substrate W, ozone molecules that decompose before hot AOM is supplied to the substrate W can be reduced.

In the present preferred embodiment, the silicon layer 100 is etched with hot AOM until the etching stop layer 101 is exposed. Hot AOM is a liquid that etches the etching stop layer 101 at an etching rate lower than the etching rate of the silicon layer 100. When the etching stop layer 101 is exposed, hot AOM contacts the etching stop layer 101 and etching of the etching stop layer 101 begins. When the etching of the silicon layer 100 is non-uniform, only a portion of the etching stop layer 101 is exposed, and then the entire etching stop layer 101 is exposed. In this case, the etching stop layer 101 is also non-uniformly etched. By improving the uniformity of the etching of the silicon layer 100, non-uniform etching of the etching stop layer 101 can be reduced.

In the present preferred embodiment, the thickness of the etching stop layer 101 is smaller than the thickness by which hot AOM etches the silicon layer 100. When the etching of the silicon layer 100 is non-uniform, the etching stop layer 101 is also non-uniformly etched by hot AOM. In this case, when the etching stop layer 101 is thin, there is a possibility that a portion of the etching stop layer 101 penetrates. By improving the uniformity of the etching of the silicon layer 100, non-uniform etching of the etching stop layer 101 can be reduced. As a result, the etching stop layer 101 can be thinned, and the material and time required to manufacture the etching stop layer 101 can be reduced.

In the present preferred embodiment, by supplying hot AOM to the substrate W, the silicon layer 100 corresponding to a plate-shaped base material made of a silicon single crystal is etched from the rear surface side of the silicon layer 100. As a result, the entire silicon layer 100 is removed from the substrate W. The etching stop layer 101 corresponds to a thin film that is in contact with the front surface of the base material. When all of the silicon layer 100 is removed from the substrate W, hot AOM contacts the etching stop layer 101. Since the uniformity of etching of the silicon layer 100 when hot AOM is supplied is improved, even if the etching stop layer 101 is etched by hot AOM, it is possible to reduce uneven etching of the etching stop layer 101. Furthermore, since all of the silicon layer 100 is removed, the amount to be etched by hot AOM is large, but since the etching rate of the silicon layer 100 is increased, an increase in time required to remove the silicon layer 100 can be reduced.

In the present preferred embodiment, before the high-temperature ammonia water is supplied to the substrate W, a processing liquid containing hydrofluoric acid such as DHF is supplied to the substrate W as a natural oxide film removing liquid. As a result, the natural oxide film 105 of the silicon layer 100 is removed. Therefore, as compared with a case where the natural oxide film 105 is not removed, hot AOM can be efficiently brought into contact with the silicon layer 100, and the silicon layer 100 can be efficiently etched. Furthermore, when foreign matter such as particles adheres to the natural oxide film 105, the foreign matter can be removed together with the natural oxide film 105, and the cleanliness of the substrate W can be enhanced.

In the present preferred embodiment, hot water as an example of a heating liquid is supplied to the lower surface of the substrate W in a state where hot AOM is in contact with the upper surface of the substrate W. If the temperature of hot water is higher than the temperature of hot AOM, the temperature of hot AOM may be increased. If the temperature of hot water is less than or equal to the temperature of hot AOM, the rate at which the temperature of hot AOM decreases can be reduced. In either case, the time required to remove the silicon layer 100 can be shortened as compared with the case where hot water is not supplied to the lower surface of the substrate W.

In the present preferred embodiment, thinning of the substrate W is performed by supplying high-temperature ammonia water to the substrate W. That is, the silicon layer 100 is etched in the thickness direction of the substrate W over the entire region from the center of the substrate W to the outer periphery of the substrate W to reduce the entire thickness of the substrate W. As a result, the entire substrate W becomes thin. Since the uniformity when the silicon layer 100 is etched by hot AOM is improved, the entire substrate W can be uniformly thinned. In addition, since the etching rate when the silicon layer 100 is etched by hot AOM is increased, the time required to thin the substrate W can be shortened.

Next, other preferred embodiments will be described.

The etching target may not be a single crystal of silicon such as the silicon layer 100, but may be polysilicon which is an aggregate of single crystals of silicon. Alternatively, both the single crystal of silicon and polysilicon may be the etching target.

Instead of mixing ozone water and ammonia water, ozone gas may be dissolved in ammonia water at room temperature or higher. The dissolved oxygen concentration of ammonia water may be increased by dissolving gas other than ozone gas such as oxygen gas in ammonia water at room temperature or higher. Alternatively, water in which a gas other than ozone gas is dissolved may be mixed with ammonia water at room temperature or higher to increase the dissolved oxygen concentration of ammonia water. That is, when the temperature of high-temperature ammonia water is higher than room temperature and the dissolved oxygen concentration of high-temperature ammonia water is increased, the high-temperature ammonia water not containing ozone gas may be supplied to the substrate W.

The substrate W to which hot AOM is to be supplied may be a substrate W other than the bonded substrate W including the first silicon wafer W1 and the second silicon wafer W2 bonded together.

Hot AOM may be supplied to the substrate W in a process other than the thinning step.

Instead of removing hot AOM from the substrate W after etching all of the silicon layer 100 with hot AOM, hot AOM may be removed from the substrate W with a portion of the silicon layer 100 remaining on the substrate W. In this case, in addition to or instead of the thickness direction of the substrate W, the etching target may be etched in the plane direction of the substrate W orthogonal to the thickness direction of the substrate W. The etching target may be covered with a thin film other than the etching target, such as a resist pattern.

Two or more of ammonia water, ozone water, and hot water may be mixed in a place other than the etching liquid piping 32c. For example, ammonia water, ozone water, and hot water may be mixed in the etching liquid nozzle 31c. When two of ammonia water, ozone water, and hot water are mixed at a first mixing position such as the tank 41e or the etching liquid piping 32c, the remaining one of ammonia water, ozone water, and hot water may be mixed with two of ammonia water, ozone water, and hot water at a second mixing position different from the first mixing position.

After DHF is supplied and before hot AOM is supplied, a processing liquid other than DHF and hot AOM such as hydrofluoric nitric acid may be supplied to the substrate W. Alternatively, after hot AOM is supplied and before the substrate W is dried, a processing liquid other than DHF and hot AOM may be supplied to the substrate W.

In addition to the wet processing step, the processing unit 2 may perform a step included in the thinning step other than the wet processing step. The plurality of processing units 2 may include a processing unit 2 that performs a step included in the thinning step other than the wet processing step, in addition to at least the wet processing unit that performs the wet processing step. In this case, the substrate W may be conveyed between the plurality of processing units 2.

Instead of discharging the chemical liquid, the rinse liquid, and the first etching liquid from separate nozzles, two or more of them may be discharged from one nozzle.

The substrate processing apparatus 1 is not restricted to an apparatus to process a disc-shaped substrate W, and may be an apparatus to process a polygonal substrate W.

If the rear surface (upper surface of the silicon layer 100 in FIG. 1C) of the substrate W is etched with high-temperature ammonia water such as hot AOM, and the front surface (lower surface of the silicon substrate 200 in FIG. 1C) of the substrate W is not etched or hardly etched with high-temperature ammonia water, the substrate processing apparatus 1 may be a batch type apparatus that collectively processes a plurality of substrates W.

Two or more arrangements among all the arrangements described above may be combined. Two or more steps among all the steps described above may be combined.

The preferred embodiments of the present invention are described in detail above, however, these are just detailed examples used for clarifying the technical contents of the present invention, and the present invention should not be limitedly interpreted to these detailed examples, and the spirit and scope of the present invention should be limited only by the claims appended hereto.

What is claimed is:

1. A substrate processing method, comprising:
preparing a substrate including an etching target that is at least one of silicon and polysilicon; and
etching the etching target by supplying the substrate with high-temperature ammonia water having a temperature higher than room temperature and an increased dissolved oxygen concentration.

2. The substrate processing method according to claim 1, further comprising:
generating the high-temperature ammonia water by mixing ammonia water, ozone water, and hot water having a temperature higher than room temperature.

3. The substrate processing method according to claim 2, wherein
etching the etching target includes discharging the high-temperature ammonia water from an etching liquid nozzle, and
generating the high-temperature ammonia water includes mixing the ammonia water, the ozone water, and the hot water in a path to the etching liquid nozzle excluding a tank to store the ammonia water.

4. The substrate processing method according to claim 1, wherein
etching the etching target includes exposing an etching stop layer covered with the etching target, by etching the etching target, and
the high-temperature ammonia water is a liquid that etches the etching stop layer at an etching rate lower than an etching rate of the etching target.

5. The substrate processing method according to claim 4, wherein a thickness of the etching stop layer is smaller than a thickness by which the high-temperature ammonia water etches the etching target.

6. The substrate processing method according to claim 1, wherein
the substrate includes a plate-shaped base material made of a silicon single crystal having a front surface and a rear surface, and a thin film that is in contact with the front surface of the base material, and
etching the etching target includes removing the entire base material by etching the base material corresponding to the etching target from the rear surface side of the base material.

7. The substrate processing method according to claim 1, further comprising:
removing a natural oxide film of the etching target by supplying a natural oxide film removing liquid to the substrate before supplying the high-temperature ammonia water to the substrate.

8. The substrate processing method according to claim 1, wherein
etching the etching target includes supplying the high-temperature ammonia water to an upper surface of the substrate, and
the substrate processing method further comprises supplying a heating liquid having a temperature higher than room temperature to a lower surface of the substrate in a state where the high-temperature ammonia water is in contact with the upper surface of the substrate.

9. The substrate processing method according to claim 1, wherein etching the etching target includes etching the etching target in a thickness direction of the substrate in an entire region from a center of the substrate to an outer periphery of the substrate to thin an entirety of the substrate by supplying the high-temperature ammonia water to the substrate.

10. A substrate processing apparatus comprising:
a substrate holder configured to hold a substrate including an etching target that is at least one of silicon and polysilicon; and
an etching liquid nozzle configured to etch the etching target by supplying the substrate held by the substrate holder with high-temperature ammonia water having a temperature higher than room temperature and an increased dissolved oxygen concentration.
